(19) United States
(12) Patent Application Publication
(10) Pub. No.: US 2020/0152918 A1
(43) Pub. Date: May 14, 2020

(54) LIGHT EMITTING DEVICE AND MANUFACTURING METHOD THEREOF

(71) Applicant: INT TECH CO., LTD., HSINCHU COUNTY (TW)

(72) Inventors: CHIH WEI LIU, HSINCHU COUNTY (TW); YIHSIN LAN, TAIPEI (TW)

(21) Appl. No.: 16/191,084

(22) Filed: Nov. 14, 2018

(51) Int. Cl. H01L 51/52; H01L 51/50; H01L 27/32; H01L 51/56

(52) U.S. Cl. CPC H01L 51/5284; H01L 51/525; H01L 51/5012; H01L 27/3272; H01L 51/5092; H01L 51/56; H01L 51/5056; H01L 51/5072; H01L 27/3258

(57) ABSTRACT

A light emitting device includes a transistor and a light emitting pixel over the transistor. The light emitting pixel includes an organic light emitting material and a transparent electrode. The transparent electrode is between the organic light emitting material and the transistor. The light emitting device includes a black material (BM) between the transistor and the transparent electrode. The light emitting device further includes a via surrounded by the BM and the via is electrically connected with the transistor at one end and with the transparent electrode at the other end.

### TECHNICAL FIELD

The present disclosure is related to light emitting device, especially to an organic light emitting device and manufacturing method thereof.

### BACKGROUND

Organic light emitting display has been used widely in most high end electron devices. However, due to the constraint of current technology, the pixel definition is realized by coating a light emitting material on a substrate through a mask, and often, the critical dimension on the mask cannot be smaller than 100 microns. Therefore, pixel density having 800 ppi or higher becomes a difficult task for a display maker.

### SUMMARY

A light emitting device includes a transistor and a light emitting pixel over the transistor. The light emitting pixel includes an organic light emitting material and a transparent electrode. The transparent electrode is between the organic light emitting material and the transistor. The light emitting device includes a black material (BM) between the transistor and the transparent electrode. The light emitting device further includes a via surrounded by the BM and the via is electrically connected with the transistor at one end and with the transparent electrode at the other end.

In some embodiments, the light emitting device further includes an inorganic dielectric between the transparent electrode and the BM. In some embodiments, the via has a first maximum width in the inorganic dielectric, and a second maximum width in the BM, wherein the second maximum width is about 80% of the first maximum width. In some embodiments, the light emitting device further includes a dielectric between the transistor and the BM. In some embodiments, the inorganic dielectric is configured as a hardmask to define a maximum width of the via in the BM.

A light emitting device includes a circuit tier and a light emitting pixel over the circuit tier. The light emitting device further includes a conductive via between the circuit tier and the light emitting pixel, the via electrically communicating the light emitting pixel with the circuit tier. The conductive via is surrounded by a dielectric stack including a plurality of dielectric layers, and the via in one of the plurality of dielectric layers includes a maximum width being defined by a bottom width of the via in an adjacent dielectric layer to the one of the plurality of dielectric layers

In some embodiments, the plurality of dielectric layers include an organic dielectric and an inorganic dielectric. In some embodiments, the light emitting pixel further comprises an electrode over the dielectric stack. In some embodiments, the electrode is transparent and conductive. In some embodiments, the light emitting device further includes a spacer partially covering the electrode. In some embodiments, the light emitting pixel includes a carrier injection layer partially overlapping with the spacer. In some embodiments, the light emitting pixel includes a carrier transportation layer partially overlapping with the spacer.

### BRIEF DESCRIPTION OF THE DRAWINGS

FIG. 1 to FIG. 8 illustrate several operations of a method of manufacturing of a light emitting device.

FIG. 9 is through hole in an intermediate product of a light emitting device.

FIG. 10 to FIG. 13 illustrate several operations of a method of manufacturing of a light emitting device.

FIG. 14 represents an intermediate product of a light emitting device.

FIG. 15 represents an intermediate product of a light emitting device.

FIG. 16 indicates a curve showing the correlation between a planarization layer surface roughness condition and yield of a light emitting device.

FIG. 17 is a perspective view of a light emitting device.

FIG. 18 is an array of electrode of the light emitting device in FIG. 17.

### DETAILED DESCRIPTION OF THE DISCLOSURE

A light emitting device is constructed to have at least two major levels. One level is configured as a light emitting level including an array of light emitting pixels and provides luminescence for the device. The light emitting pixels can be made with organic or inorganic material. Another level is a circuit level which is electrically coupled to the light emitting level and vertically stacking with the light emitting level. The circuit level supplies power and control signals to the light emitting level in order to display the color or pattern as needed.

In order to combine the two major levels to be an integrated device, various approaches can be adopted. One of the approaches is to form the circuit level first then disposing the light emitting level over the circuit level. The circuit level is acting as a process starting substrate for forming the light emitting level thereon. Another exemplary approach is to independently form the circuit level and the light emitting level on separate substrates, then bonding the circuit level and the light emitting level to form an integrated light emitting device. However, no matter which approach is chosen, the flatness of the contact surface on each side is critical to the yield of forming the integrated light emitting device.

The present disclosure provides a solution to form a flat surface on the circuit level in order to improve the manufacturing yield. The solution can apply to various integration approaches as mentioned above. In some embodiments, the present disclosure provides a flat uppermost surface for the circuit level. The flat uppermost surface is a starting surface to dispose an array of light emitting pixels. In some embodiments, the arrangement of the pixels in the array is determined through a photolithography operation. In the present disclosure, the arrangement of the pixels means that the position, light emitting area, or other geometric characteristics of each pixel is defined in the photolithography operation.

In some embodiments, the pixel array is formed by form an array of conductive pads on the uppermost surface of the circuit level. The array of conductive pads can be formed by patterning a conductive sheet at least through photolithography or etch operation. The uppermost surface is partially covered by the conductive pads. The conductive pads can be electrically connected with the conductive traces in the circuit level through several conductive vias. A photomask is disposed to substantially cover the areas unoccupied by the conductive pads and form trench on a conductive pad. Emission layer or other layers such as carrier transportation or injection layer can be disposed into the trench to form a light emitting pixel. In some embodiments, the carrier transportation or injection layer is disposed over the conductive pads and unoccupied areas before the photomask is disposed. Since the photolithography operation is used in several process steps to form the light emitting pixel array, this explains why the flatness of the uppermost surface of the circuit level is a critical factor to the manufacturing yield.

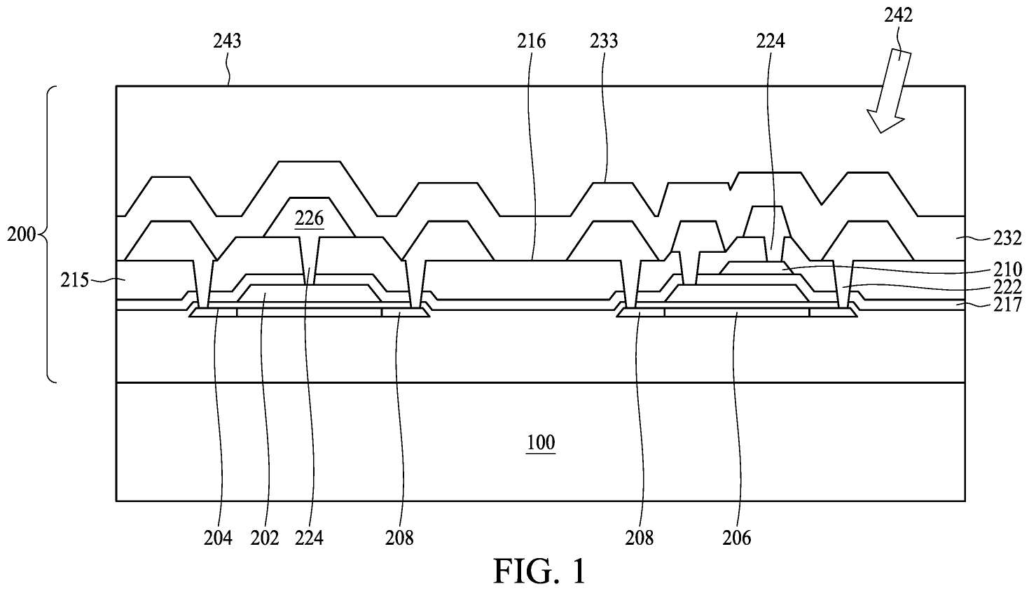

FIG. 1 is illustrates an operation of forming a light emitting device according to some embodiments of the disclosure. In the operation, a substrate 100 is provided. The substrate 100 can be a glass, a semiconductive material such as silicon, III-V group compound, or other suitable material. In some embodiments, substrate 100 includes graphene.

In some embodiments, substrate 100 might be formed with a polymer matrix material. Substrate 100 has a bend radius being not greater than about 3 mm. In some embodiments, substrate 100 has a minimum bend radius being not greater than 10 mm. The minimum bend radius is measured to the inside curvature, is the minimum radius one can bend substrate 100 without kinking it, damaging it, or shortening its life.

A circuit tier 200 is disposed over the substrate 100. The circuit tier 200 may have several transistors and each transistor may have a gate 202 over a channel 206. The gate 202 can be made with conductive material such as metal, or silicide. In some embodiments, the gate 202 can be a composite structure including several different layers and the different layers may be distinguishable after applying etchant and observed under microscope. The channel 206 may be made with semiconductive material such as silicon, or other element selected from group IV, or group III and V.

In the transistor, a gate dielectric 204 is between the gate 202 and the channel 206. The gate dielectric 204 can be silicon oxide, ONO (silicon oxide-silicon nitride-silicon oxide), hi-K (dielectric constant greater than 10 or 12) dielectric such as hafnium silicate, zirconium silicate, hafnium dioxide and zirconium dioxide, etc. Source/drain 208 is disposed on opposite side of the channel 206 to provide carriers.

Conductive features are formed to connect with the transistor. Conductive features may include some conductive vias 222, which are connected to the source/drain regions 208 of the transistor at one end. Conductive features may include some conductive vias 224, which are connected to the gate 202 of the transistor or a capacitor metal 210 at one end. Conductive features may include some conductive traces 226, which are configured as interconnect between different transistors or other electronic component in the circuit tier 200.

Dielectric 215 is disposed between the transistors and the conductive traces 226. In some embodiments, dielectric 215 may include more than one layer as shown in FIG. 1. Conductive vias 222 and 224 respectively penetrate through the dielectric 215. Dielectric 215 is conformal to the topography of the transistors and capacitor disposed over substrate 100. Therefore, a top surface 216 of dielectric 217 can be up and down and follows the topography of the transistors and capacitor under the dielectric 215.

Total height of each conductive via may be different because the penetration depth of each via is determined by the total thickness of the dielectric 215 and the other films under the dielectric. For example, via 224 connected to the capacitor metal 210 has a shorter total height than via 224 connected to gate 202 because the via 224 connected to gate 202 needs to further penetrate through a dielectric 217, which is between gate 202 and capacitor metal 210. Similarly, via 224 connected to gate 202 has a shorter total height than via 222 connected to source/drain regions 208.

Another dielectric 232 is disposed to cover the conductive traces 226. In some embodiments, dielectric 232 includes silicon nitride in order to be more resistant to moisture and acid than dielectric 215. In some embodiments, dielectric 232 is conformal to the conductive vias and traces 226 in order to provide better protection to the conductive traces 226. Therefore, similar to the dielectric 215, a top surface 233 of the dielectric 232 up and down and follows the topography of conductive vias and traces thereunder.

A planarization layer 242 is optionally disposed over the top surface 233 of the dielectric 232. Compared to the dielectric 232 and 215, the planarization layer 242 has a higher capability to gap filling. Therefore, if there is any recess on the top surface 233, the planarization layer 242 fills the recess to minimize the roughness of the top surface 233. Further, the planarization layer 242 also provides a flat surface 243 for proceeding operations. In some embodiments, the planarization layer 242 is a black material (BM). In some embodiments, the planarization layer 242 is a spin on glass (SOG) containing inorganic material such as silicon oxide or silicon oxynitride. The planarization layer 242 may have a thickness between about 400 nm and about 700 nm.

The planarization layer 242 can be formed by various methods including vapor deposition, jetting, spin coating, atomic layer deposition. In some embodiments, the planarization layer 242 is also a dielectric and can be made with an organic or an inorganic material. In one case, the planarization layer 242 is made with black material, which absorbs visible lights substantially.

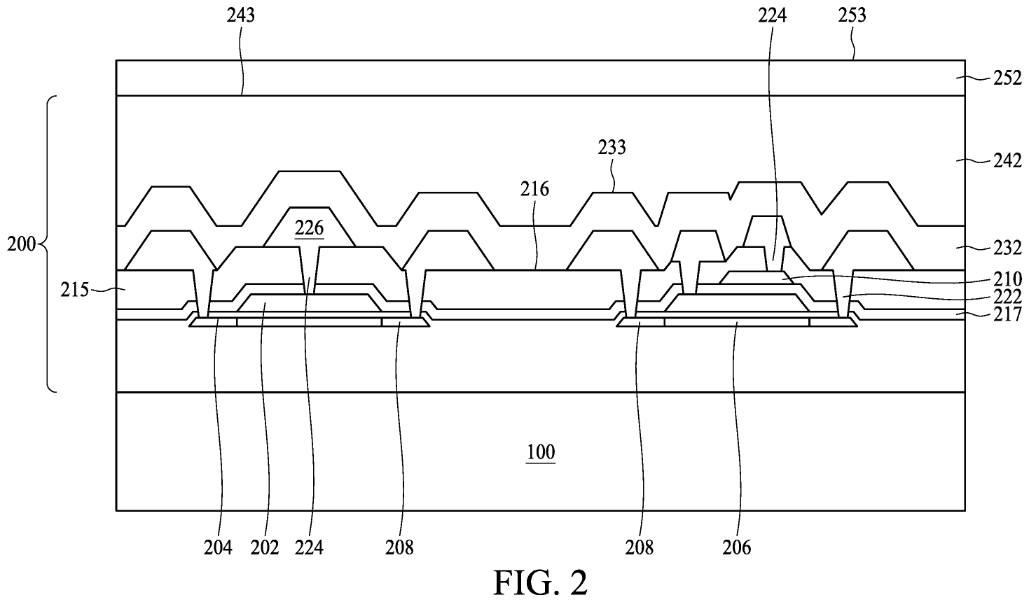

Another dielectric 252 is optionally disposed over the planarization layer 242 as shown in FIG. 2. The dielectric 252 is selected from a material different from the planarization layer 242. One of the reasons to use different materials between dielectric 252 and planarization layer 242 is to increase the selectivity between dielectric 252 and planarization layer 242 for some proceeding etch operations.

In one embodiment, the dielectric 252 is made with inorganic material and the planarization layer 242 is made with organic material. The dielectric 252 may be made with silicon oxide, silicon nitride, silicon oxynitride, or other suitable materials. The dielectric 252 can be optionally blanket disposed on the planarization layer 242. In one embodiment, the planarization layer 242 is made with inorganic material and there is no extra dielectric 252 needed.

In some embodiments, the dielectric 252 has a higher resistance to O₂ plasma than the planarization layer 242. The dielectric 252 has a higher resistance to photo resist stripping solution than the planarization layer 242.

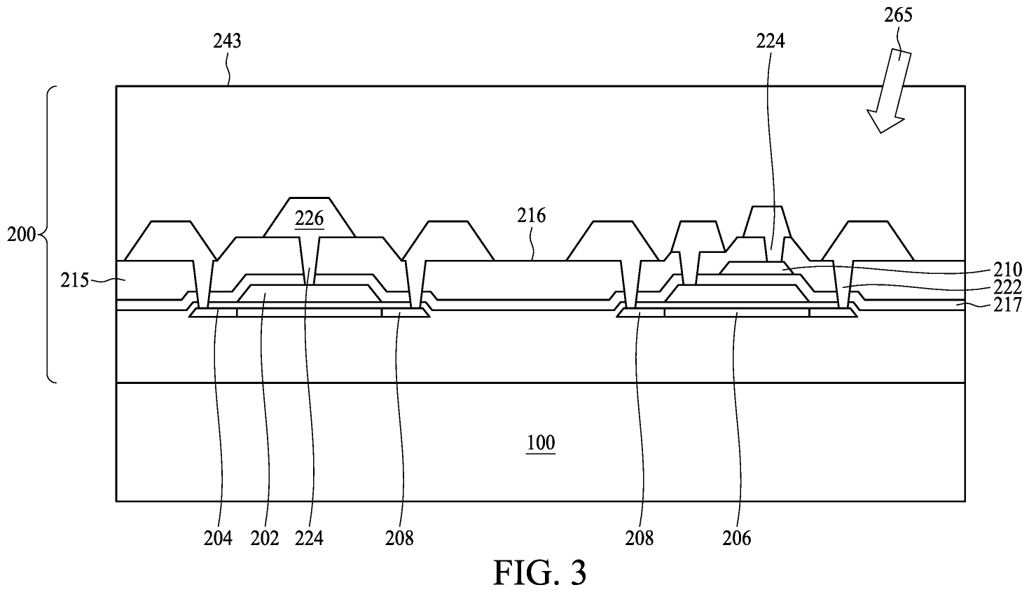

FIG. 3 illustrates another embodiment showing how to form a dielectric covering transistors and capacitor. Comparing to the embodiments in FIG. 1 and FIG. 2, the embodiment in FIG. 3 only uses one layer dielectric 265 to cover the transistors and capacitor. The dielectric 265 is directly in contact with the transistors or the capacitor. The dielectric 265 can be made with inorganic material.

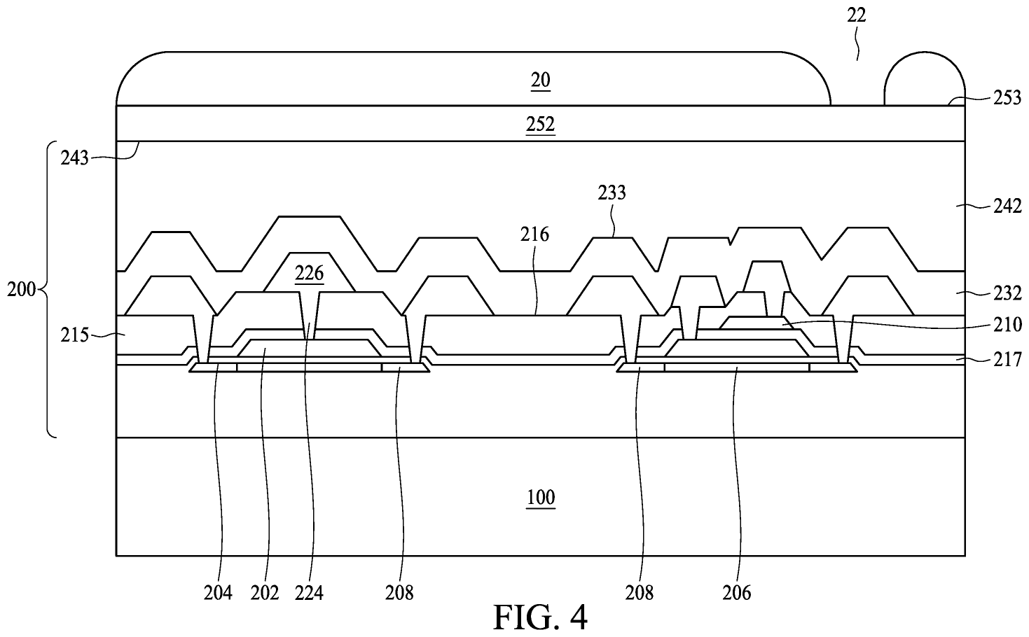

FIG. 4 illustrates an operation of forming an opening in the dielectric of the circuit tier in FIG. 2. A mask 20 is disposed to cover the surface 253 of the dielectric 252. The mask 20 can include photosensitive material. The mask 20 is patterned to expose a portion of the surface 253. To pattern a photosensitive mask 20 can be done through a photolithography process including exposure, developing and other suitable operations.

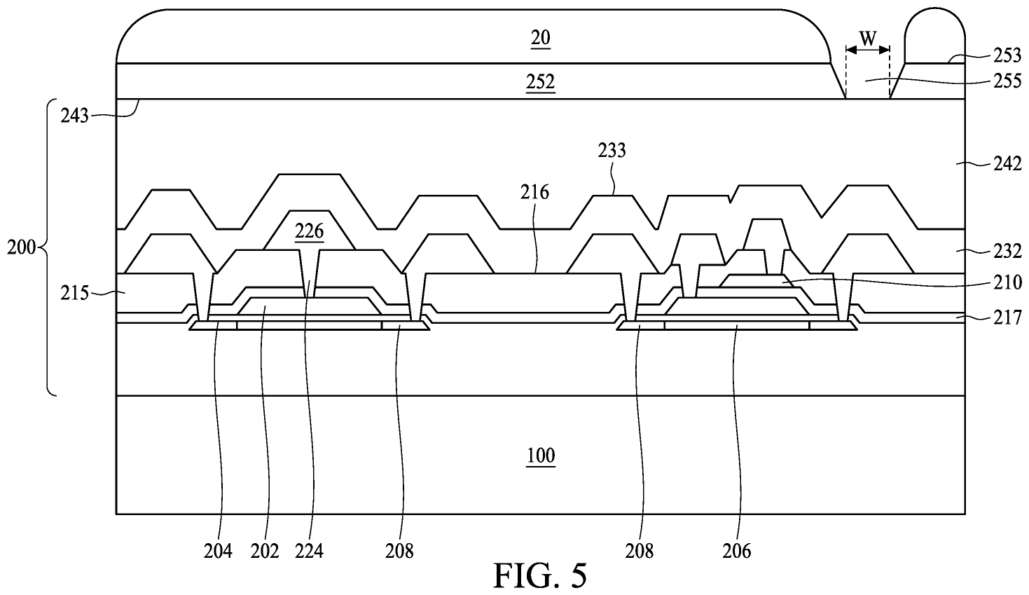

After forming through hole 22 in the mask 20 to partially the surface 253, a portion of the dielectric 252 is removed to form a through hole 255 in the dielectric 252 as shown in FIG. 5. A portion of the planarization layer 242 is exposed from the through hole 255. In some embodiments, the through hole 255 is tapered and the maximum width decreases from the top toward the planarization layer 242. The sidewall of the through hole 255 can be a slanted from top to planarization layer 242, or can be a curvature with an arc surface.

To form the through hole 255 can be performed through an anisotropic etch. During the anisotropic etch, an etchant plasma is formed in a chamber then directed toward the substrate 100. The etchant plasma may include fluorine, carbon, or silicon. A bias voltage can be applied on the substrate 100 during etch.

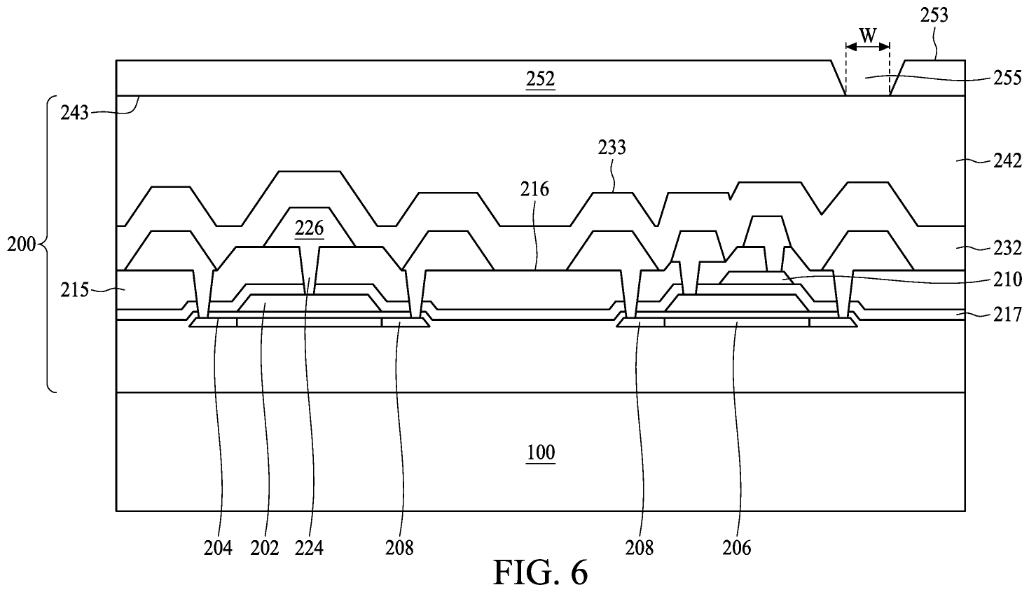

In some embodiments, the mask 20 is removed after forming the through hole 255 in the dielectric 252 as shown in FIG. 6. The dielectric 252 is configured as a hardmask to define a maximum width of the via in the planarization layer 242. The patterned dielectric 252 can be utilized as a mask to define via hole in the planarization layer 242. The max width at the bottom of the through hole 255, W, is used to define the dimension of the via hole to be formed in the planarization layer 242. Introducing the dielectric 252 to be over the planarization layer 242 allows shrinking the critical dimension of via hole in the planarization layer 242 to be smaller than the size of the photo mask hole 22, which is defined by a photolithography process. The bottom width W is reduced from top by controlling the removal operation in FIG. 5. The taper angle of the through hole 255 can be changed to a desired value by manipulating the parameters of the removal operation, for example, the RF power, bias voltage applied on the substrate 100, or chamber pressure etc.

After forming the through hole 255 in the dielectric 252, the dielectric 252 becomes a hardmask laid over the planarization layer 242. As mentioned, the bottom width W determines the dimension of a to-be-formed through hole in the planarization layer 242. In some embodiments, the bottom width W is the largest dimension of the through hole in the planarization layer 242.

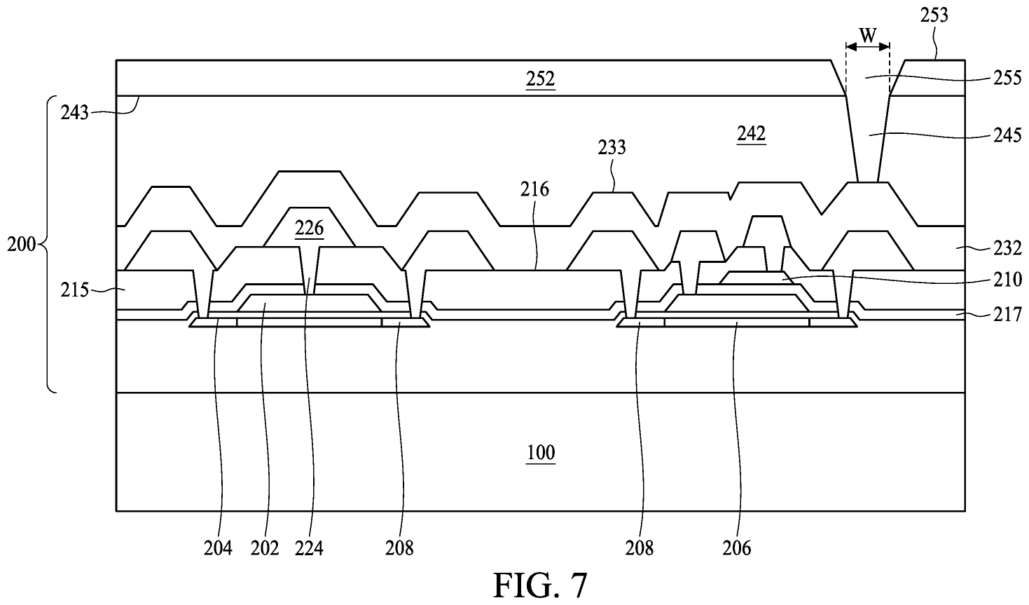

If the planarization layer 242 substantially contains organic material, oxygen gas can be introduced to perform a top-down etch on the planarization layer 242. The oxygen gas is ionized and transformed into plasma prior to the top-down etch. FIG. 7 shows that a through hole 245 is formed in the planarization layer 242 after the top-down etch. Sidewall of the through hole 245 may taper down from the top, i.e. the top end has a widest dimension. The oxygen plasma etch may stop at the dielectric 232 if an inorganic material is adopted for the dielectric 232.

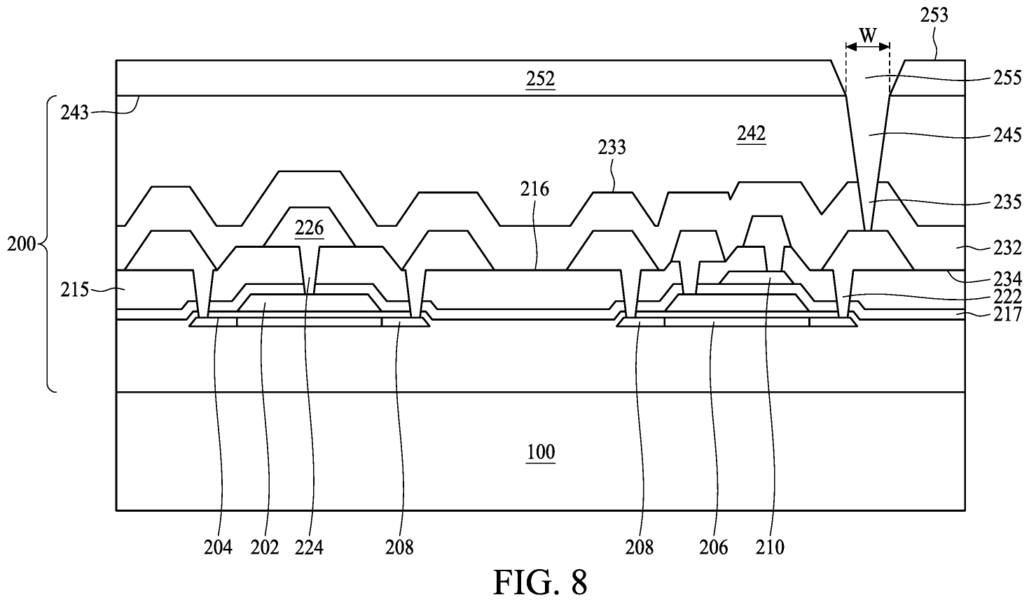

In some embodiments, the dielectric 232 is silicon oxide, which is resistant to the oxygen plasma. The etchant is switched from oxygen plasma to an oxide etchant in order to form a hole through the dielectric 232. A through hole 235 is formed in the dielectric 232 as shown in FIG. 8. The through hole 235 expose a portion of conductive trace or conductive via. In some embodiment, the exposed surface, a surface uncovered by the dielectric 232, of the conductive trace or conductive via is lower than the bottom surface 234 of the dielectric because the conductive trace or conductive via is also partially removed by the oxide etchant.

In some embodiments, the tapered angle of through hole 235 is different from that of through hole 245. Sidewall slope of the through hole 235 may be greater than that of through hole 245. In some embodiments, sidewall slope of the through hole 245 may be greater than that of through hole 255. In some embodiments, all three through holes have a same tapered angle.

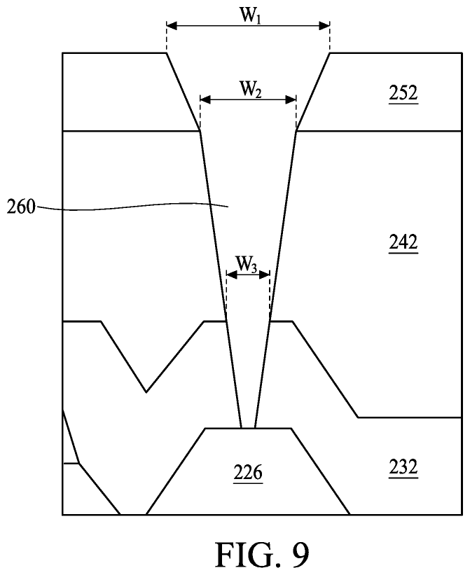

FIG. 9 is an enlarged view of the through holes in FIG. 8. Dielectric 252 can be a silicon nitride or silicon oxide film. In one embodiment, a total thickness of dielectric 252 is between about 40 nm and about 130 nm. In one embodiment, a total thickness of dielectric 252 is between about 60 nm and about 120 nm. In one embodiment, a total thickness of dielectric 252 is between about 80 nm and about 115 nm.

Planarization layer 242 can be an organic black material. In one embodiment, a total thickness of dielectric 242 is between about 500 nm and about 900 nm. In one embodiment, a total thickness of dielectric 242 is between about 600 nm and about 850 nm. In one embodiment, a total thickness of dielectric 242 is between about 450 nm and about 800 nm.

Dielectric 232 can be a silicon nitride or silicon oxide film. In one embodiment, a total thickness of dielectric 232 is between about 150 nm and about 425 nm. In one embodiment, a total thickness of dielectric 232 is between about 100 nm and about 600 nm. In one embodiment, a total thickness of dielectric 232 is between about 150 nm and about 400 nm.

Through holes 235, 245, and 255 altogether form a through via 260 in the circuit tier. The through via 260 has a first width W₁, which is the dimension at the upper most of the through via 260, and can be the maximum width of via 260 in dielectric 252. The through via 260 has a second width W₂, which is the dimension at the interface between dielectric 242 and dielectric 252 of the through via 260, and can be the maximum width of via 260 in dielectric 242. The through via 260 has a second width W₃, which is the dimension at the interface between dielectric 242 and dielectric 232, and can be the maximum width of via 260 in dielectric 232. In some embodiments, the first width W₁ is greater than the second width W₂, and the second width W₂ is greater than the third width W₃. In some embodiments, the first width W₁ is smaller than about 0.5 μm and the second width W₂ is about 80% or less than the first width W₁. In some embodiments, the third width W₃ is about 80% or less than the second width W₂.

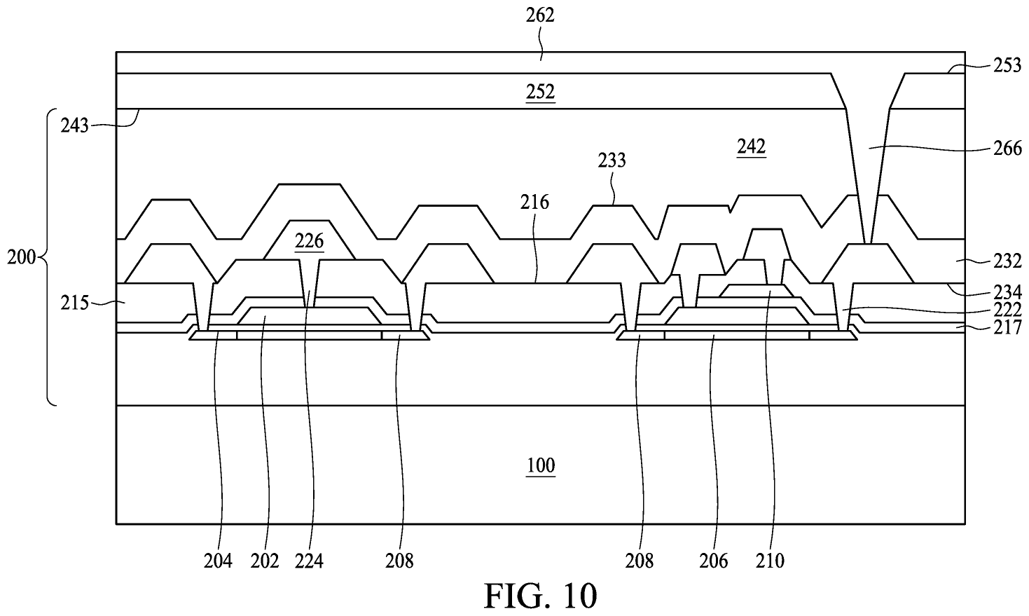

A conductive material 262 is disposed over the dielectric 252 and fills the though via 260 to form a conductive via 266 as shown in FIG. 10. The conductive material 262 can be metal such as Al, Cu, Ag, Au, W, etc. or metal alloy. In some embodiments, the conductive material 262 can be transparent metal oxide such as indium tin oxide (ITO), indium zinc oxide (IZO), aluminum-doped zinc oxide (AZO) and indium-doped cadmium oxide, etc. In some embodiments, the conductive material 262 is in direct contact with the dielectric 252.

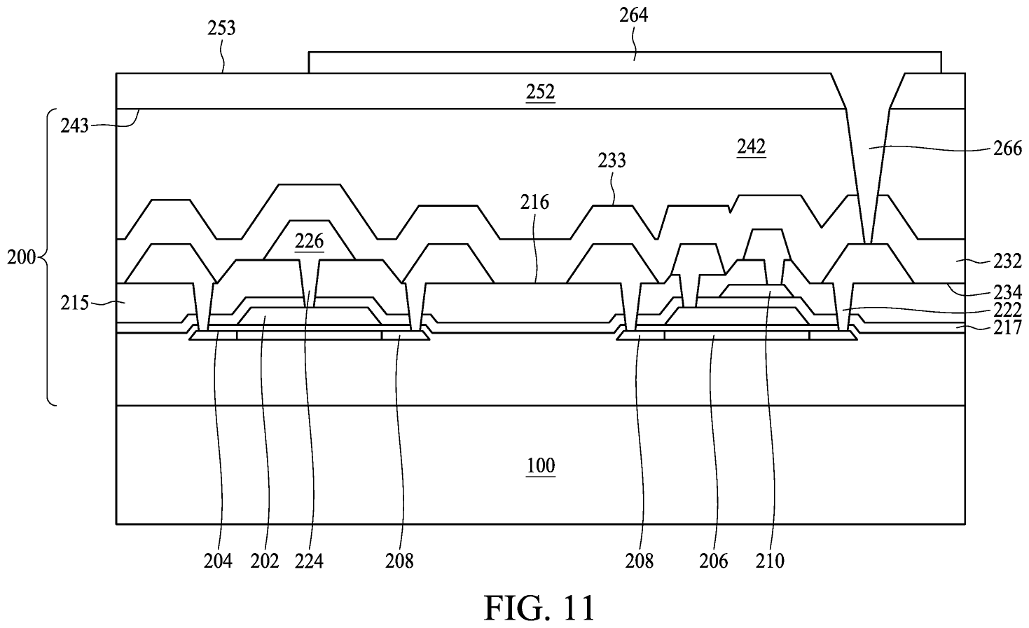

The conductive material 262 is patterned to form several electrodes 264 as shown in FIG. 11. In the drawing, only one electrode is illustrated. The electrode 264 is prepared for a light emitting unit to electrically communicating with the circuit tier. In some embodiments, the electrode 264 is designed as an anode of the light emitting unit. In some embodiments, the light emitting unit is an organic light emitting unit.

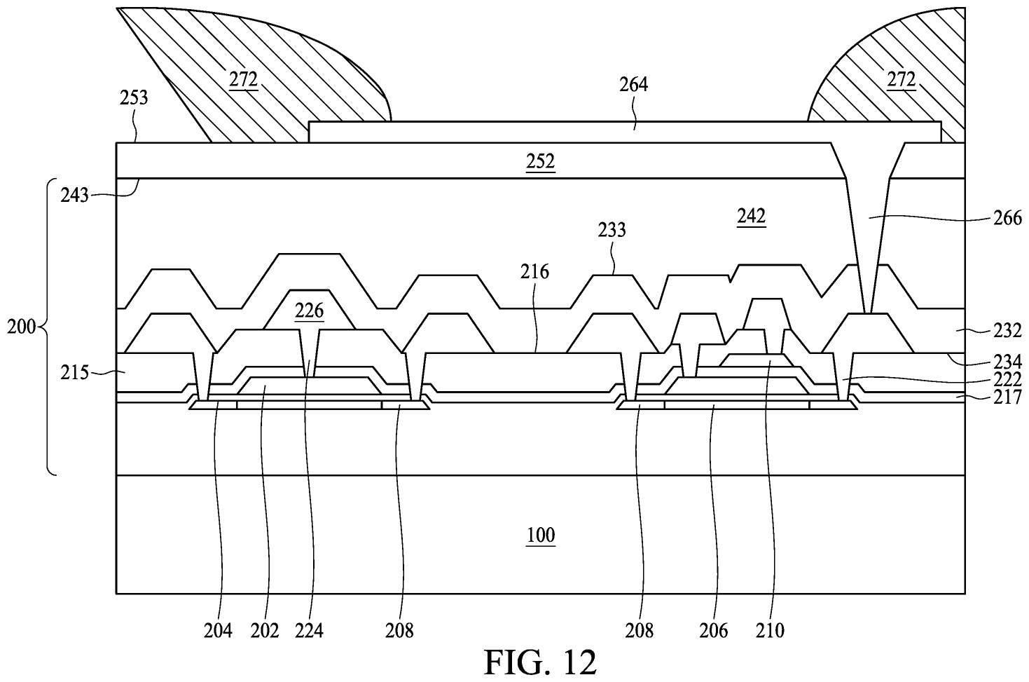

After forming the electrode 264, spacer 272 can be optionally disposed over the inorganic dielectric 252 as in FIG. 12. In some embodiments, the spacer 272 partially covers the electrode 264 and leaves a portion of the electrode 264 open to receive light emitting material. In some embodiments, the spacer 272 includes polymeric material. In some embodiments, the spacer 272 includes photosensitive material. In some embodiments, the spacer 272 is a photo absorption material as the planarization material 242. In some embodiments, the spacer 272 is used as a pattern defined layer. In some embodiments, the patterned spacer 272 is fluorine free, i.e. substantially contains no fluorine. In some embodiments, the spacer 272 is formed through a photolithography operation.

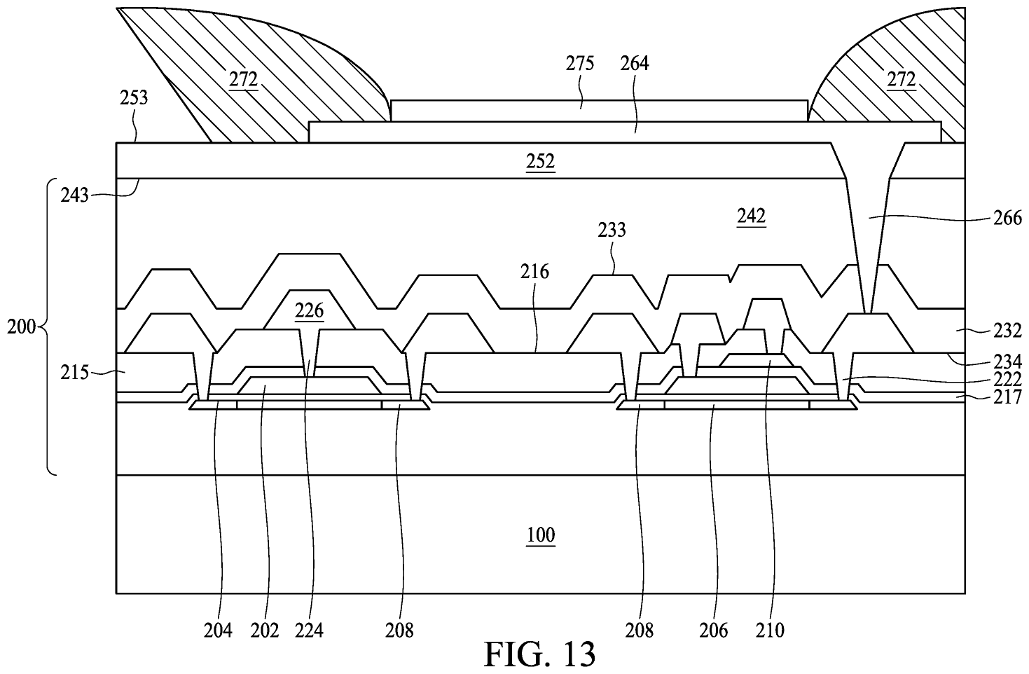

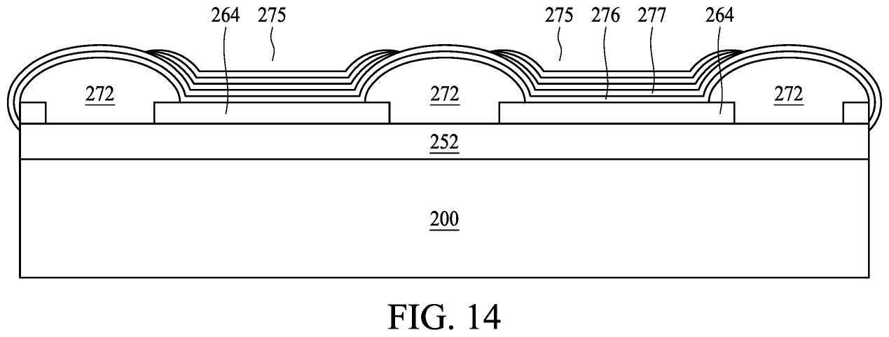

Light emitting material 275 is disposed on the electrode 264 as shown in FIG. 13. In some embodiments, the light emitting material 275 includes a first carrier injection layer disposed over the exposed surfaces of the spacer 272 and the electrode 264. The first carrier injection layer is continuously lining along the exposed surfaces. More specifically, the exposed surface of each electrode 264 is configured as an effective light emitting area for one light emitting unit. In this embodiment, all light emitting units use a common first carrier injection layer. In some embodiments, first carrier injection layer is for hole injection. In some embodiments, first carrier injection layer is for electron injection. The first carrier injection layer 276 continuously overlies several spacers 272 and electrode 264 as in FIG. 14. Optionally, the carrier injection layer 276 is in contact with the spacers 272. In one embodiment, the carrier injection layer 276 is in contact with the first electrodes 215. In some embodiments, the carrier injection layer 276 is organic.

A carrier transportation layer 277 (or called first type carrier transportation layer) is disposed over the exposed surfaces of the spacers 272 and the electrode 264. The carrier injection layer 276 is disposed under the first carrier transportation layer 277. The carrier transportation layer 277 is continuously lining along the first carrier transportation layer 277. In this embodiment, all light emitting units use a common carrier transportation layer 277. In some embodiments, carrier transportation layer 277 is for hole transportation. In some embodiments, layer 277 is for electron transportation. The carrier transportation layer 277 continuously overlies several spacers 272 and first electrodes 264. Optionally, the carrier transportation layer 277 is in contact with the first carrier injection layer 276. In some embodiments, the carrier transportation layer 277 is organic.

As shown in FIG. 13 and FIG. 14, the light emitting material 275 may have several sublayers stacked over the electrode 264. In some embodiments, each sublayer may be relatively thinner than the electrode 264 or the total thickness of circuit tier 200. In some embodiments, a thickness of a sublayer in the light emitting material 275 is in nanometer scale and a thickness of the planarization layer 242 is in micrometer scale. Therefore the flatness of the planarization layer 242 is critical to the on-board performance of the light emitting material 275.

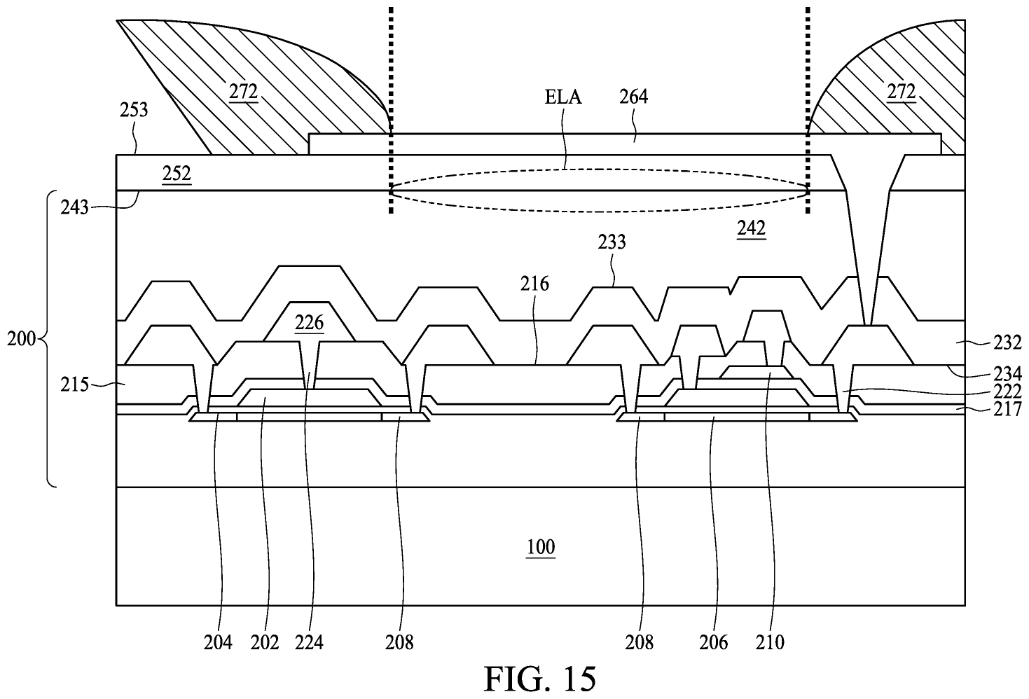

One way to define the flatness of the planarization layer 242 in the present disclosure is to use a localize flatness LF to characterize the flatness of the surface 243 of the planarization layer 242. An effective local area ELA on the surface 243 is determined as in FIG. 15. In some embodiments, the ELA is substantially equal to the area of an effective light emitting area of each light emitting unit or pixel. The effective light emitting area is the uncovered area of the electrode 264, i.e. the area of electrode exposed from the spacers 272. In some cases, the ELA is vertically aligned with an effective light emitting area of the light emitting unit or pixel.

One way to define an LF in an ELA is to follow ISO 4287 standard, using mean line system to define the LF. In some embodiments, the LF is represented by Rᵥ, the maximum valley depth, or Rₚ, the maximum peak height. In some embodiments, the IRᵥI or IRₚI of the planarization layer 242 should be controlled not greater than about 50 times of a thickness of any sublayer in the light emitting material 275. For example, if the first carrier injection layer 276 is the thinnest sublayer in the light emitting material 275, the IRᵥl or IRₚI is not greater than about 50 times of the thickness of the first carrier injection layer 276. If the IRᵥI or IRₚI is 50 or more times greater than the thickness of the first carrier injection layer 276, the first carrier injection layer 276 becomes vulnerable and may be easily broken at the largest step. The sublayer also can be a hole transportation layer, an emitting layer, or an electron transportation layer.

The surface asperity of the surface 243 is different from the top surface 233 of the dielectric 232. In some embodiments, the IRᵥI or IRₚI of the surface 243 is about one third of less than the IRᵥI or IRₚI of the surface 233. In some embodiments, the roughness of the flatness of the planarization layer 242 is corresponding to the flatness of the electrode 264. In some embodiments, the arithmetic average of the roughness profile (Ra) of the electrode 264 is smaller than about 15 nm in order to facilitate preceeding photolithography operations for forming light emitting pixels. In some embodiments, the arithmetic average of the roughness profile (Ra) of the electrode 264 is smaller than about 10 nm. In some embodiments, the peak to valley (Rmax) of the electrode 264 is smaller than about 50 nm in order to facilitate preceeding photolithography operations for forming light emitting pixels. In some embodiments, the peak to valley (Rmax) of the electrode 264 is smaller than about 40 nm in order to facilitate preceeding photolithography operations for forming light emitting pixels.

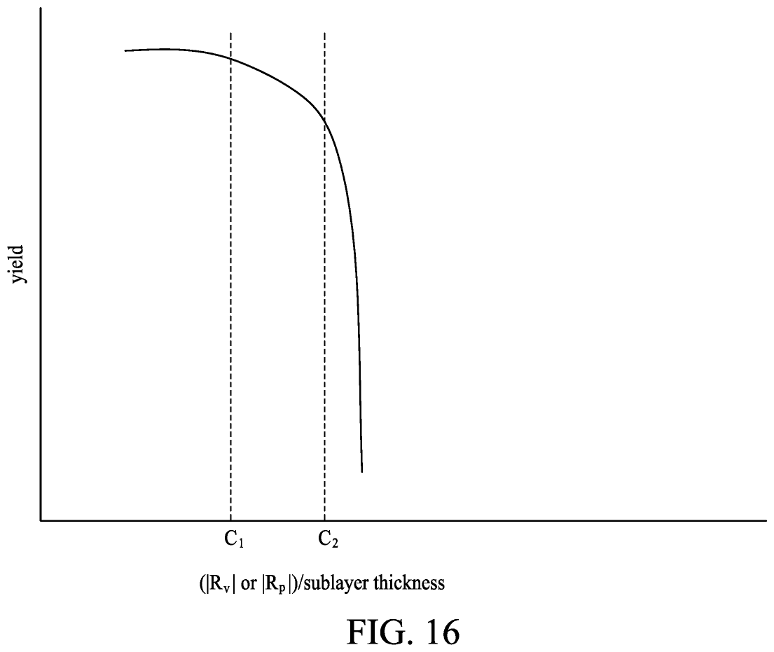

The yield is defined as a percentage of good light emitting units (or pixels) in a predetermined light emittng pixel array. As in FIG. 16, the Y-axis represents yield of a light emitting pixel array and the X-axis represents the ratio of the IRᵥI or IRₚI to a sublayer's thickness. When the ratio reaches C₁, the yield has a about 5% degradation from peak yield. When the ratio reaches C₂, the yield abruptly drops to become to be about 15% lower than the peak yield. When the ratio is greater than C₂, the yield may breakdown immediately. In some embodiments, the peak yield is about 99% or more.

In some cases, C₂ is about 50. In some cases, C₂ is about 60. In some cases, C₂ is about 100. In some cases, C₂ is about 150. The variation is dependent on the material of the sublayer. In some cases, C₁ is about 10. In some cases, C₁ is about 20. In some cases, C₁ is about 25. In some cases, C₁ is about 30.

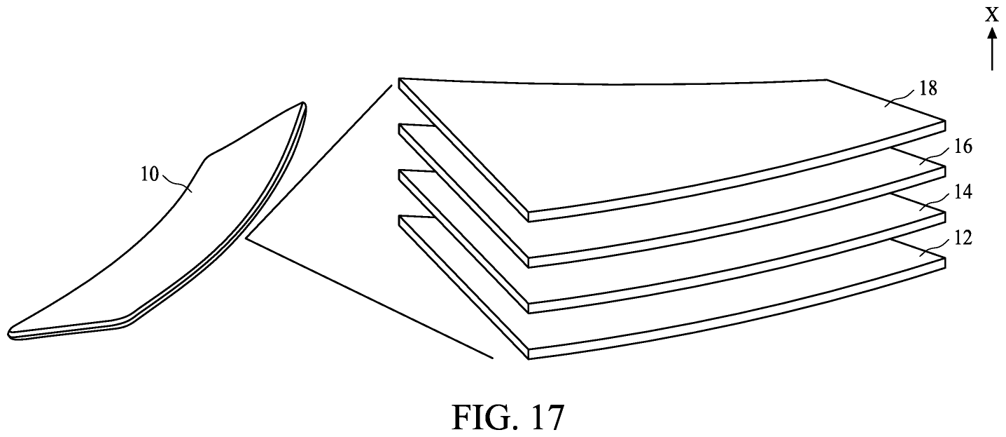

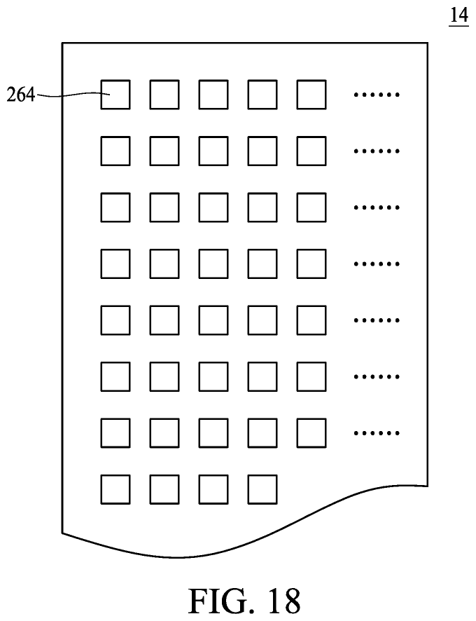

FIG. 17 shows a light emitting device 10 including a light emitting layer 14. The light emitting layer 14 includes an aforementioned light emitting pixel array. The light emitting pixel array can be an ultra high pixel density array (for example, over 2000 ppi). The light emitting pixel array includes an array of electrodes 264 as shown in FIG. 18. In some embodiments, the mean value of the electrodes 264 is smaller than about 10 um.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A light emitting device, comprising:
a transistor;
a light emitting pixel over the transistor, the light emitting pixel including an organic light emitting material and a transparent electrode, the transparent electrode between the organic light emitting material and the transistor;
a black material (BM) between the transistor and the transparent electrode;
a via surrounded by the BM, the via electrically connected with the transistor at one end and with the transparent electrode at the other end.

2. The light emitting device in claim 1, further comprising an inorganic dielectric between the transparent electrode and the BM.

3. The light emitting device in claim 2, wherein the via has a first maximum width in the inorganic dielectric, and a second maximum width in the BM, wherein the second maximum width is about 80% of the first maximum width.

4. The light emitting device in claim 1, further comprising a dielectric between the transistor and the BM.

5. The light emitting device in claim 2, wherein the inorganic dielectric is configured as a hardmask to define a maximum width of the via in the BM.

6. A light emitting device, comprising:
a circuit tier;
a light emitting pixel over the circuit tier; and
a conductive via between the circuit tier and the light emitting pixel, the via electrically communicating the light emitting pixel with the circuit tier,
wherein the conductive via is surrounded by a dielectric stack including a plurality of dielectric layers, and the via in one of the plurality of dielectric layers includes a maximum width being defined by a bottom width of the via in an adjacent dielectric layer to the one of the plurality of dielectric layers.

7. The light emitting device of claim 6, wherein the plurality of dielectric layers include an organic dielectric and an inorganic dielectric.

8. The light emitting device of claim 6, wherein the light emitting pixel further comprises an electrode over the dielectric stack.

9. The light emitting device of claim 8, wherein the electrode is transparent and conductive.

10. The light emitting device of claim 8, further comprising a spacer partially covering the electrode.

11. The light emitting device of claim 10, wherein the light emitting pixel includes a carrier injection layer partially overlapping with the spacer.

12. The light emitting device of claim 10, wherein the light emitting pixel includes a carrier transportation layer partially overlapping with the spacer.
